(19) United States
(12) Patent Application Publication
(10) Pub. No.: US 2009/0176350 A1
(43) Pub. Date: Jul. 9, 2009

(54) INTEGRATION OF ION GETTERING MATERIAL IN DIELECTRIC

(75) Inventors: MICHAEL P. BELYANSKY, Bethel, CT (US); Brian J. Greene, Wappingers Falls, NY (US); Habib Hichri, Poughkeepsie, NY (US); Tai-Chi Su, Woodbury (TW)

Correspondence Address: FREDERICK W. GIBB, III;Gibb Intellectual Property Law Firm, LLC, 2568-A RIVA ROAD, SUITE 304, ANNAPOLIS, MD, 21401, US

(73) Assignee: INTERNATIONAL BUSINESS MACHINES CORPORATION, ARMONK, NY (US)

(21) Appl. No.: 11/969,272

(22) Filed: Jan. 4, 2008

(51) Int. Cl. H01L 21/322

(52) U.S. Cl. 438/473; 257/E21.317

(57) ABSTRACT

A method embodiment deposits a first dielectric layer over a transistor and then implants a gettering agent into the first dielectric layer. After this first dielectric layer is formed, the method forms a second (thicker) dielectric layer over the first dielectric layer. After this, the standard contacts are formed through the insulating layer to the source, drain, gate, etc. of the transistor. Additionally, reactive ion etching, chemical mechanical processing, and other back-end-of-line processing are performed. The back-end-of-line processes can introduce mobile ions into the dielectric over a transistor; however, the gettering agent traps the mobile ions and prevents the mobile ions from contaminating the transistor.

### CROSS-REFERENCE TO RELATED APPLICATIONS

This application is related to U.S. application Ser. No. ______, having Attorney Docket Number FIS920070357US1, entitled “STRUCTURE AND METHOD TO IMPROVE MOSFET RELIABILITY, filed concurrently herewith, the complete disclosure of which, in its entirety, is herein incorporated by reference.

### BACKGROUND

### Field of the Invention

The embodiments of the invention generally relate to integrated circuit devices and more particularly to a method that implants a gettering agent into insulating layers of transistors, where the gettering agent traps mobile ions and prevents the mobile ions from contaminating the underlying transistor.

### SUMMARY

More specifically, one method embodiment herein deposits a first dielectric layer over a transistor and then implants a gettering agent into the first dielectric layer. The gettering agent can comprise Phosphorus, Arsenic, Nitrogen, etc. After this first dielectric layer is formed, the method forms a second (thicker) dielectric layer over the first dielectric layer. After this the standard contacts (tungsten) are formed through the insulating layer to the source, drain, gate, etc. of the transistor. Additionally, reactive ion etching of the contacts is performed. The reactive ion etching process and subsequent processes used in semiconductor fabrication can introduce mobile ions into the dielectric layer immediately above the transistor; however, the gettering agent traps the mobile ions and prevents the mobile ions from contaminating the transistor.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a schematic diagram of a transistor structure according to embodiments herein; and

FIG. 2 is a schematic diagram of a transistor structure according to embodiments herein.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

Mobile ion contamination is a constant threat to semiconductor device performance and reliability. Mobile ions (i.e., K, Na, Li, etc.) can shift the threshold voltage of field effect transistors (FETs) substantially, which causes reliability issues. Many mobile ions are often unintentionally transferred to semiconductor wafers by sputtering from contaminated reactive ion etching (RIE) processes, contaminated chemical mechanical polish (CMP) chemicals and tooling, etc. that are performed after the conductive contacts Tungsten, Copper, etc.) to the various elements of the transistors/diodes (source, drain, gate, base, emitter, collector, etc.) are formed.

For many years, the sensitive front-end-of-the-line (FEOL) devices have been protected from mobile ion contaminants by phosphorus doped glass (Phosphosilicate (PSG), or Borophosphosilicate (BPSG), etc.) and contact-etch-stop nitride liners before proceeding to the back-end for metallization. However, current technology process limitations are not compatible with traditional BPSG process requirements. For example, the BPSG reflow temperatures needed for adequate conformality and gap-fill are incompatible with the thermal stability limits of nickel silicide (NiSi). Additional protection against mobile ion contamination is often obtained through the use of a contact etch stop silicon nitride liner. In recent technology these contact etch stop liners have played a critical role in device performance, by engineering the silicon nitride liners to high strain levels (>1 GPa). However, in some instances, Nitride stress optimization may not be consistent with mobile ion protection. While lower temperature PSG solutions are available, such solutions require special tooling.

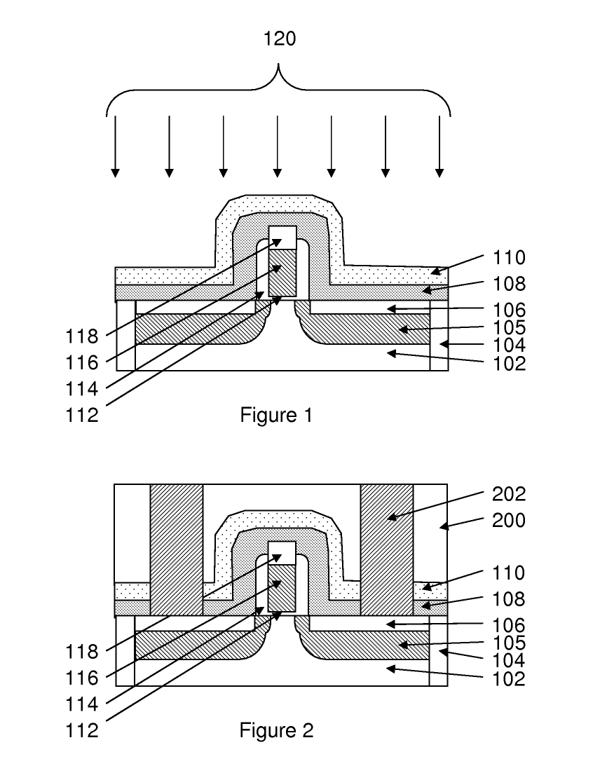

FIG. 1 illustrates a typical field effect transistor upon which embodiments herein operate. Such a field effect transistor includes a substrate 102 having a channel region; shallow trench isolation regions 104; source/drain regions 105 capped with a low resistance silicide region 106; a gate oxide 112; a gate conductor 114 above the gate oxide 112; a silicide or other low resistance conducting layer 118 at the top of the gate conductor 116; sidewall spacers 114 along the sides of the gate conductor 116; and an etch stop layer (nitride) 108. The various deposition, patterning, polishing, etching, etc. processes that are performed and the material selections that are made in the creation of such field effect transistors are well known as evidence by U.S. Pat. No. 6,995,065 (which is incorporated herein by reference) and the details of such processing are not discussed herein to focus the reader on the salient aspects of the invention. Further, while one type of specific device is illustrated in the drawings, those ordinarily skilled in the art would understand that the invention is not strictly limited to the specific device shown, but instead that the invention is generally applicable to all similar devices that suffer disadvantageously from mobile ions.

One solution to the foregoing problems presented in this disclosure is a dual layer middle-of-the-line (MOL) dielectric incorporating a gettering agent. This embodiment deposits a conformal first dielectric layer 110 (oxide, un-doped silicate glass (USG), etc.) over the nitride etch stop layer 108 of the transistor and then performs a surface implant 120 of a gettering agent into the first dielectric layer, as shown in FIG. 1. The gettering agent can comprise Phosphorus, Arsenic, Nitrogen, etc. After this first dielectric layer 110 is formed and implanted, the method forms a second (thicker) dielectric layer 200 as a cap over the first dielectric layer 110. The first dielectric layer 110 can be the same or a different material than the second dielectric layer 200.

After this, standard contacts 202 (Tungsten, Copper, etc.) are formed through the insulating layer to the source, drain, etc. of the transistor. Additionally, reactive ion etching of the contacts 202 is performed as part of the finalization/cleaning of the contacts. As mentioned above, this reactive ion etching process can create mobile ions; however, the gettering agent traps the mobile ions and prevents the mobile ions from contaminating the transistor.

By utilizing a dual layer dielectric, a high-dose, low energy implant 120 can be utilized to create a gettering layer 110 sufficient to protect the underlying devices from mobile ion contamination. However, because the upper second dielectric 200 has acceptable physical characteristics, the dual layer dielectric does not present problems relating to gap-fill, conformality, and mechanical stability. To the contrary, if the entire dielectric layer (including the second layer 200) included gettering material, such a dielectric would not be as conformal and would present gap-fill, conformality, and mechanical stability issues. In other words, by utilizing two separate layers, any disadvantageous effects that may be caused by the less conformal first dielectric layer are overcome by the acceptable conformal nature of the second dielectric layer.

The foregoing processing is easily accomplished with toolsets in common usage in modern semiconductor processing (i.e., inexpensive) and no specialized tooling is required. Further, with embodiments herein, the choice of dielectric does not require the elevated temperature processing needed for PSG, because the second dielectric layer can be optimized for conformality and gap fill without compromising the mobile ion gettering function of the middle of line dielectric. Further, the utilization of the dual layer dielectric minimizes the required implant dose to achieve effective gettering concentrations, and therefore permits a low energy implant, which lowers the risk of nitride damage from high implant energy tails. Further, with embodiments herein the chemical-mechanical polishing (CMP) process window is independent from doped oxide properties, because the doped dielectric (110) is protected from such processing by the overlying second, undoped dielectric 200.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A method comprising:
depositing a first dielectric layer over a transistor;
implanting a gettering agent into said first dielectric layer;
forming a second dielectric layer over said the first dielectric layer, wherein said second dielectric layer is thicker than said first dielectric layer; and
forming contacts through said insulating layer to said transistor.

2. The method according to claim 1, all the limitations of which are incorporated herein by reference, wherein said gettering agent comprises one of Phosphorus, Arsenic, and Nitrogen

3. The method according to claim 1, all the limitations of which are incorporated herein by reference, wherein said second dielectric layer is thicker than said first dielectric layer.

4. A method comprising:
depositing a first dielectric layer over a transistor;
implanting a gettering agent into said first dielectric layer;
forming a second dielectric layer over said the first dielectric layer, wherein said second dielectric layer is thicker than said first dielectric layer;
forming contacts through said insulating layer to said transistor; and
performing reactive ion etching of said contacts, wherein said reactive ion etching creates mobile ions, and wherein said gettering agent traps said mobile ions and prevents said mobile ions from contaminating said transistor.

5. The method according to claim 4, all the limitations of which are incorporated herein by reference, wherein said gettering agent comprises one of Phosphorus, Arsenic, and Nitrogen

6. The method according to claim 4, all the limitations of which are incorporated herein by reference, wherein said second dielectric layer is thicker than said first dielectric layer.
